(19) United States
(12) Patent Application Publication
(10) Pub. No.: US 2025/0130500 A1
(43) Pub. Date: Apr. 24, 2025

(54) METHODS FOR FORMING EUV RESIST UNDERLAYER

(71) Applicant: Applied Materials, Inc., Santa Clara, CA (US)

(72) Inventors: Sudha RATHI, San Jose, CA (US); Rui WANG, Santa Clara, CA (US); Pramit MANNA, Santa Clara, CA (US); Karthik JANAKIRAMAN, San Jose, CA (US)

(21) Appl. No.: 18/923,789

(22) Filed: Oct. 23, 2024

Related U.S. Application Data
(60) Provisional application No. 63/592,681, filed on Oct. 24, 2023.

(51) Int. Cl. G03F 7/16; H01J 37/32

(52) U.S. Cl. CPC G03F 7/167; H01J 37/32146; H01J 37/32165; H01J 37/32522; H01J 37/32816; H01J 2237/3321

(57) ABSTRACT

The present disclosure generally relates to semiconductor processing and, in particular, provides methods of forming a resist underlayer on a substrate for use in EUV lithography processing. In an embodiment, the method includes flowing a precursor gas mixture into the processing region of the process chamber, applying a pulsed RF power to the precursor gas mixture to generate a plasma in the processing region, depositing a resist underlayer on the substrate with the plasma generated from the pulsed RF power, and forming a patterned chemically amplified photoresist (CAR) over the resist underlayer.

### CROSS-REFERENCE TO RELATED APPLICATIONS

This application claims priority to U.S. Provisional Patent Application Ser. No. 63/592,681, filed on Oct. 24, 2023, which herein is incorporated by reference.

### BACKGROUND

### Field

Embodiments of the present disclosure generally relate to the field of semiconductor processing and, in particular, to methods of forming a resist underlayer for use in EUV lithography processing.

### Description of the Related Art

As geometries of the electronic devices shrink, lithography and patterning for electronic device designs become more challenging. A single lithographic exposure may not be enough to provide sufficient resolution. Typically, for manufacturing integrated circuits (ICs), multiple patterning techniques and additional metal layers are used to increase the feature density. The multiple-patterning techniques and implementation of the additional metal layers complicate the manufacturing technology and are expensive.

The demands for greater integrated circuit densities also impose demands on the process sequences used in the fabrication of integrated circuit components. For example, process sequences that employ conventional lithography techniques for semiconductor device manufacturing employs primarily four steps. These steps include (1) photoresist or “resist” coating; (2) exposure; (3) wet development; and (4) etch. The photoresist coating may include a layer of energy sensitive resist formed over a stack of material layers deposited on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer.

Generally, extreme ultraviolet (EUV) lithography uses EUV wavelength that is much shorter than the wavelengths of the conventional techniques to scale down the feature sizes on the IC chips. Typically, the EUV lithography uses the EUV resist patterned using a EUV wavelength that is about 13.5 nm. The EUV resist, however, is much less resistant to etching than the photoresist used for conventional patterning techniques. Currently, the integrity of the EUV resist pattern resulted from etching is very poor comparing to that of the conventional photoresists. To use EUV lithography to form features on a substrate, a resist underlayer is typically deposited on a substrate, and then an EUV photoresist is deposited over the resist underlayer. As the feature size of the device decreases, the resist underlayer may preferably be thinner to allow the formation of etched features with a desired resolution or aspect ratio.

The lithography processes described above may suffer from several drawbacks. For instance, wet development of resists may produce a pattern having resist line-edge-roughness (LER) due to an acid gradient at mask edges. This may cause uncertainty in predicting line edges that result following wet development. Additionally, as device dimensions shrink, capillary forces due to the small feature size may cause pattern collapsing during wet development and cleaning processes. High aspect ratio patterns are also increasingly being utilized to improve resist roughness performance and provide more etch resistance to allow a wider margin of etch transfer. However, high aspect ratio patterns can also increase the tendency for pattern collapse. Although capillary force may be a main cause of pattern collapse, other factors that can also influence pattern collapse include the adhesion force between the photoresist and the underlayer resist film. To enable further miniaturization of resist pattern transfer for EUV lithography, addressing pattern collapse and etch resistance of the resist are important.

Accordingly, there is a need in the art for improved underlayer resist films and methods for forming the same.

### SUMMARY

In one embodiment, a method for processing a substrate is provided. The method includes disposing a substrate in a processing region of a process chamber, flowing a precursor gas mixture into the processing region of the process chamber, applying a pulsed RF power to the precursor gas mixture to generate a plasma in the processing region, and depositing a resist underlayer on the substrate with the plasma generated from the pulsed RF power. After the resist underlayer is deposited on the substrate using the pulsed plasma, a patterned chemically amplified photoresist (CAR) is formed over the resist underlayer.

In another embodiment, a method for processing a substrate is provided. The method includes disposing a substrate in a processing region of a process chamber and depositing a hardmask layer over the substrate. The method also includes flowing a precursor gas mixture into the processing region of the process chamber, applying a RF power to the hydrocarbon-containing gas mixture to generate a plasma in the processing region, and pulsing the RF power at a pulse frequency between about 10 Hz to about 2000 Hz, and at a duty cycle between about 10% and about 90%. The pulsed plasma is used to deposit a resist underlayer on the hardmask layer. The method continues with forming a patterned chemically amplified photoresist (CAR) over the resist underlayer.

In yet another embodiment, a method of processing a substrate is provided. The method includes flowing a hydrocarbon-containing gas mixture into a processing region of the process chamber having a substrate disposed therein, applying a pulsed RF power to the hydrocarbon-containing gas mixture to generate a plasma in the processing region, and depositing a resist underlayer on the substrate with the plasma generated from the pulsed RF power. The method also includes performing a surface treatment process to form a surface layer on the resist underlayer to modify a surface energy of the resist underlayer, forming a chemically amplified photoresist (CAR) over the resist underlayer, and patterning the CAR with a wet chemical process to form a patterned CAR over the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a schematic cross-sectional view of a process chamber that can be used for the practice of the method of the present disclosure, according to certain embodiments described herein;

FIG. 2 is a process flow diagram depicting a method for depositing a resist underlayer, according to certain embodiments escribed herein;

FIG. 3 is a schematic view of an example filmstack formed using the method in FIG. 2, according to certain embodiments of the present disclosure;

FIG. 4 is a process flow diagram depicting a method for treating a resist underlayer, according to certain embodiments escribed herein; and

FIG. 5 is a table depicting changes in adhesive work between a photoresist and a substrate due to resist underlayers formed in accordance with certain embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of forming a resist underlayer for use in EUV lithography processes is described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

In general, several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

To provide context, as feature and device sizes decrease, the stack thickness is correspondingly reduced. As such, the resist underlayer may preferably also be thinner (e.g., 10 A-50 A) to allow the formation of etched features with a desired resolution and/or aspect ratio. As the thickness of the underlayer resist film decreases, the adhesion at the interface between the resist underlayer and the EUV photoresist can decrease due to mis-matched surface energies between the two materials. Poor adhesion between the resist underlayer and the EUV photoresist can result in poor line width roughness (LWR), line pattern collapse (LPR), and/or other lithography related defects.

The present disclosure provides a method for improving adhesion between the resist underlayer and the EUV photoresist disposed thereon when the resist underlayer is less than 50 A. In an embodiment, the present disclosure provides for forming the resist underlayer utilizing RF pulsing techniques to increase adhesion between the resist underlayer and the photoresist layer disposed thereon. The methods disclosed herein can also minimize the effects of exposure of the resist underlayer to processing and/or surface treatments caused by the resist underlayer being disposed on a hardmask. In some embodiments, the methods disclosed herein improve the density of the resist underlayer and the adhesion of the resist underlayer to the hardmask when the resist underlayer is less than 50 A.

In some embodiments, the methods disclosed herein improve the adhesion between the hardmask, the resist underlayer, and the EUV photoresist. The methods disclosed herein may be optimized to match the surface energy between the layers i.e., between the hardmask and the resist underlayer, and between the resist underlayer and the EUV photoresist, to improve adhesion.

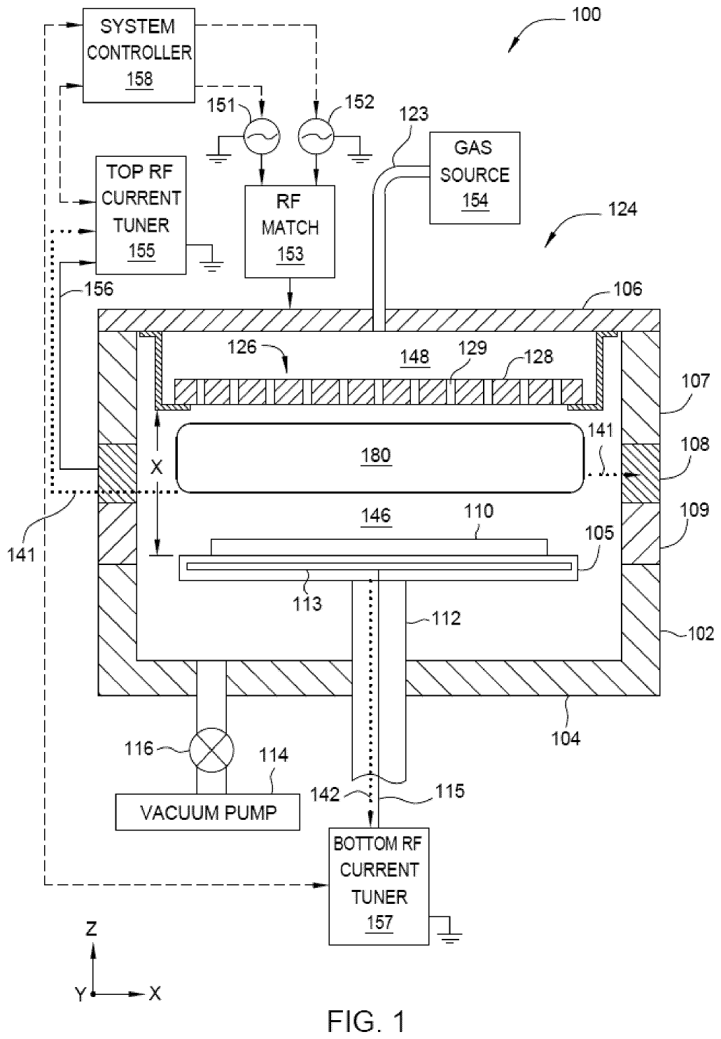

FIG. 1 is a schematic illustration of a cross sectional view of a process chamber 100 that can be used to form and treat a resist underlayer on a substrate prior to forming a patterned photoresist thereon, in accordance with embodiments described herein. By way of example, the embodiment of the process chamber 100 in FIG. 1 is described in terms of a PECVD system, but any other process chamber may fall within the scope of the embodiments, including other vapor deposition chambers or plasma deposition chambers. The process chamber 100 includes walls 102, a bottom 104, and a chamber lid 124 that together enclose a substrate support 105 and a processing region 146. The process chamber 100 further includes a vacuum pump 114, a first RF generator 151, a second RF generator 152, an RF match 153, a gas source 154, a top RF current tuner 155, a bottom RF current tuner 157, and a system controller 158, each coupled externally to the process chamber 100 as shown.

The walls 102 and the bottom 104 may comprise an electrically conductive material, such as aluminum or stainless steel. Through one or more of the walls 102, a slit valve opening may be present that is configured to facilitate insertion of a substrate 110 into and removal of the substrate 110 from the process chamber 100. A slit valve configured to seal slit valve opening may be disposed either inside or outside of the process chamber 100. For clarity, no slit valve or slit valve opening is shown in FIG. 1.

The vacuum pump 114 is coupled to the process chamber 100 and is configured to adjust the vacuum level therein. As shown, a valve 116 may be coupled between the process chamber 100 and the vacuum pump 114. The vacuum pump 114 evacuates the process chamber 100 prior to substrate processing and removes process gas therefrom during processing through the valve 116. The valve 116 may be adjustable to facilitate regulation of the evacuation rate of the process chamber 100. The evacuation rate through the valve 116 and the incoming gas flow rate from the gas source 154 determine chamber pressure and process gas residency time in the process chamber 100.

The gas source 154 is coupled to the process chamber 100 via a tube 123 that passes through the chamber lid 124. The tube 123 is fluidly coupled to a plenum 148 between a backing plate 106 and a gas distribution showerhead 128 included in the chamber lid 124. During operation, process gas introduced into the process chamber 100 from the gas source 154 fills the plenum 148 and then passes through the gas passages 129 formed in the gas distribution showerhead 128 to uniformly enter the processing region 146. In alternative embodiments, process gas may be introduced into the processing region 146 via inlets and/or nozzles (not shown) that are attached to the walls 102 in addition to or in lieu of the gas distribution showerhead 128.

The substrate support 105 may include any technically feasible apparatus for supporting a substrate during processing by the process chamber 100, such as the substrate 110 in FIG. 1. In some embodiments, the substrate support 105 is disposed on a shaft 112 that is configured to raise and lower the substrate support 105. In one embodiment, the shaft 112 and the substrate support 105 may be formed at least in part from or contain an electrically conductive material, such as tungsten, copper, molybdenum, aluminum, or stainless steel. Alternatively or additionally, the substrate support 105 may be formed at least in part from or contain a ceramic material, such as aluminum oxide (Al₂O₃), aluminum nitride (AlN), silicon dioxide (SiO₂), and the like.

In some embodiments, the substrate support 105 may include a heater element (not shown) suitable for controlling the temperature of the substrate 110 supported on the top surface of the substrate support 105. The heater element 170 may be embedded in the substrate support 105. The substrate support 105 may be resistively heated by applying an electric current from a heater power source (not shown) to the heater element. The electric current supplied from the heater power source may also be regulated by the controller 158 to control the heat generated by the heater element, thus maintaining the substrate 110 and the substrate support 105 at a substantially constant temperature during film deposition. The supplied electric current may be adjusted to selectively control the temperature of the substrate support 105 or the substrate 110 disposed thereon between about −50 degrees Celsius to about 600 degrees Celsius.

In embodiments in which the process chamber 100 is a capacitively coupled plasma chamber, the substrate support 105 may be configured to contain an electrode 113. In such embodiments, a metal rod 115 or other conductor is electrically coupled to the electrode 113 and is configured to provide a portion of a ground path for RF power delivered to the process chamber 100. That is, the metal rod 115 enables a RF power delivered to the process chamber 100 to pass through the electrode 113 and out of the process chamber 100 to ground. Together, the electrode 113 and the gas distribution showerhead 128 define the boundaries of the processing region 146 in which plasma is formed. For example, during processing, the substrate support 105 and the substrate 110 may be raised and positioned closer to the lower surface of the gas distribution showerhead 128 to form the at least partially enclosed processing region 146.

The first RF generator 151 is a radio frequency (RF) power source configured to provide high-frequency power at a first RF frequency to a discharge electrode 126 via the RF match 153. Similarly, the second RF generator 152 is an RF power source configured to provide RF power at a second RF frequency to the discharge electrode 126 via RF match 153. In some embodiments, first RF generator 151 includes an RF power supply capable of generating RF currents at a high frequency (HF), for example, about 13.56 MHz. Alternatively or additionally, the first RF generator 151 includes a VHF generator capable of generating VHF power, such as VHF power at frequencies between about 20 MHz to 200 MHz or more, such as about 27 MHz or about 40 MHz. By contrast, the second RF generator 152 includes an RF power supply capable of generating RF currents at so-called low frequency (LF) RF, for example, about 350 kHz. Alternatively or additionally, the second RF generator 152 includes an RF generator capable of generating RF power at frequencies between about 1 kHz and about 1 MHz. During a deposition or etch process, one or both of the first RF generator 151 and the second RF generator 152 provide a power of about 10 Watts (W) to about 10,000 W in the processing region 146 to facilitation ionization of a precursor gas. In one embodiment, which can be combined with other embodiments described herein, at least one of the first RF generator 151 and the second RF generator 152 are pulsed. The first RF generator 151 and the second RF generator 152 are configured to facilitate generation of a plasma in the processing region 146 between the discharge electrode 126 and the substrate support 105.

The discharge electrode 126 may include a process gas distribution element, such as the gas distribution showerhead 128 (as shown in FIG. 1), and/or an array of gas injection nozzles, through which process gases are introduced into the processing region 146. The discharge electrode 126, i.e., the gas distribution showerhead 128, may be oriented substantially parallel to the surface of the substrate 110, and capacitively couples plasma source power into the processing region 146, which is disposed between the substrate 110 and the gas distribution showerhead 128.

The RF match 153 may be any technically feasible impedance matching apparatus that is coupled between the first RF generator 151 and the powered electrode of the process chamber 100, i.e., the gas distribution showerhead 128. The RF match 153 is also coupled between the second RF generator 152 and the powered electrode of the process chamber 100. The RF match 153 is configured to match a load impedance (the process chamber 100) to the source or internal impedance of a driving source (the first RF generator 151, the second RF generator 152) to enable the maximum transfer of RF power from the first RF generator 151 and the second RF generator 152 to the process chamber 100.

Forming a portion of the walls 102 are an upper isolator 107, a tuning ring 108, and a lower isolator 109. The upper isolator 107 is configured to electrically isolate the tuning ring 108, which is formed from an electrically conductive material, from the backing plate 106, which in some embodiments is energized with RF power during operation. Thus, upper isolator 107 is positioned between the backing plate 106 and the tuning ring 108, and prevents the tuning ring 108 from being energized with RF power via the backing plate 106. In some embodiments, the upper isolator 107 is configured as a ceramic ring or annulus that is positioned concentrically about the processing region 146. Similarly, the lower isolator 109 is configured to electrically isolate the tuning ring 108 from the walls 102. The walls 102 are typically formed from an electrically conductive material, and can therefore act as a ground path for a portion of RF power delivered to the process chamber 100 during processing. Thus, the lower isolator 109 enables the tuning ring 108 to be part of a different ground path for RF power delivered to the process chamber 100 than that of the walls 102. In some embodiments, the upper isolator 107 is configured as a ceramic ring, or is configured to include a ceramic ring that is positioned concentrically about the processing region 146.

The tuning ring 108 is disposed between the upper isolator 107 and the lower isolator 109, is formed from an electrically conductive material, and is disposed adjacent the processing region 146. For example, in some embodiments, the tuning ring 108 is formed from a suitable metal, such as aluminum, copper, titanium, or stainless steel. In some embodiments, the tuning ring 108 is a metallic ring or annulus that is positioned concentrically about the substrate support 105 and the substrate 110 during processing of the substrate 110. In addition, the tuning ring 108 is electrically coupled to ground via the top RF current tuner 155 via a conductor 156, as shown. Thus, the tuning ring 108 is not a powered electrode, and is generally disposed outside of and around the processing region 146. In one example, the tuning ring 108 is positioned in a plane substantially parallel with the substrate 110, and is part of a ground path for the RF energy used to form a plasma in the processing region 146. As a result, an additional RF ground path 141 is established between the gas distribution showerhead 128 and ground, via the top RF current tuner 155. Thus, by changing the impedance of the top RF current tuner 155 at a particular frequency, the impedance for the RF ground path 141 at that particular frequency changes, causing a change in the RF field that is coupled to the tuning ring 108 at that frequency. Therefore, the shape of plasma in the processing region 146 may be independently modulated along the +/−X and Y-directions for the RF frequency associated with either the first RF generator 151 or the second RF generator 152. That is, the shape, volume or uniformity of the plasma formed in the processing region 146 may be independently modulated for multiple RF frequencies across the surface of the substrate 110 by use, for example, of the tuning ring 108 or vertically between the substrate 110 and the gas distribution showerhead 128 using the electrode 113.

The system controller 158 is configured to control the components and functions of the process chamber 100, such as the vacuum pump 114, the first RF generator 151, the second RF generator 152, the RF match 153, the gas source 154, the top RF current tuner 155, and the bottom RF current tuner 157. As such, the system controller 158 receives sensor inputs, e.g., voltage-current inputs from the top RF current tuner 155 and the bottom RF current tuner 157, and transmits control outputs for operation of the process chamber 100. The functionality of the system controller 158 may include any technically feasible embodiment, including via software, hardware, and/or firmware, and may be divided between multiple separate controllers associated with the process chamber 100.

The top RF current tuner 155, as noted above, is electrically coupled to the tuning ring 108 and is terminated to ground, thus providing a controllable RF ground path 141 for the process chamber 100. Similarly, the bottom RF current tuner 157 is electrically coupled to the metal rod 115 and is terminated to ground, thus providing a different controllable RF ground path 142 for the process chamber 100. As described herein, the top RF current tuner 155 and the bottom RF current tuner 157 are each configured to control the flow of RF current to ground at multiple RF frequencies. Thus, the distribution of RF current at a first RF frequency between the tuning ring 108 and the metal rod 115 can be controlled independently from the distribution of RF current at a second RF frequency between the tuning ring 108 and the metal rod 115.

A plasma 180 is formed in the processing region 146 in between the electrode 113 and the discharge electrode 126. A distance or “spacing” between the bottom surface of the electrode 113 and a top surface of the substrate support 105 is represented by “x”.

Other deposition chambers may also benefit from the present disclosure and the parameters listed above may vary according to the particular deposition chamber used to form the amorphous carbon layer. For example, other deposition chambers may have a larger or smaller volume, requiring gas flow rates that are larger or smaller than those recited for deposition chambers available from Applied Materials, Inc. In one embodiment, carbon gapfill layer may be deposited using a PRODUCER® XP Precision™ processing system, which is commercially available from Applied Materials, Inc., Santa Clara, California.

Proper control and regulation of the gas flows from the gas source 154 may be performed by mass flow controllers (not shown) and the controller 158. The gas distribution showerhead 128 allows process gases from the gas source 154 to be uniformly distributed and introduced into the processing region 146.

The first RF generator 151 and the second RF generator 152 may produce power at the same frequency or a different frequency. In some embodiments, one or both of the first RF generator 151 and the second RF generator 152 may independently produce power at a frequency from about 350 KHz to about 100 MHz (e.g., 350 KHz, 2 MHz, 13.56 MHz, 27 MHz, 40 MHz, 60 MHz, or 100 MHz). In some embodiments, the first RF generator 151 may produce power at a frequency of 13.56 MHz and the second RF generator 152 may produce power at a frequency of 2 MHz, or vice versa. RF power from one or both of the first RF generator 151 and second RF generator 152 may be varied in order to tune the generated plasma.

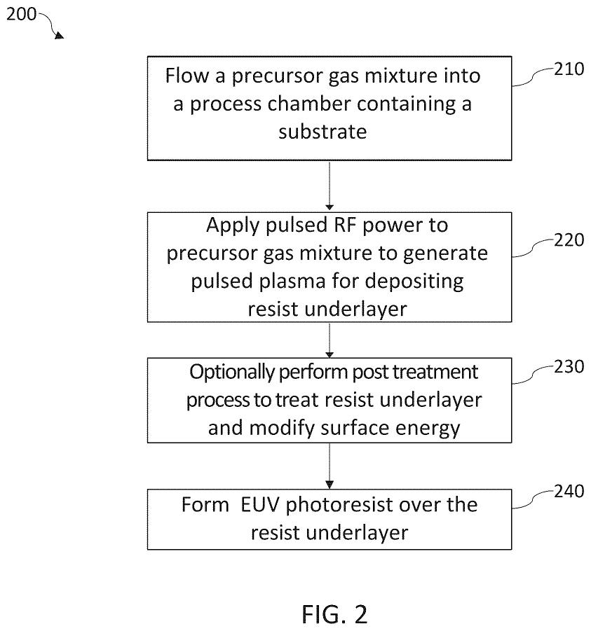

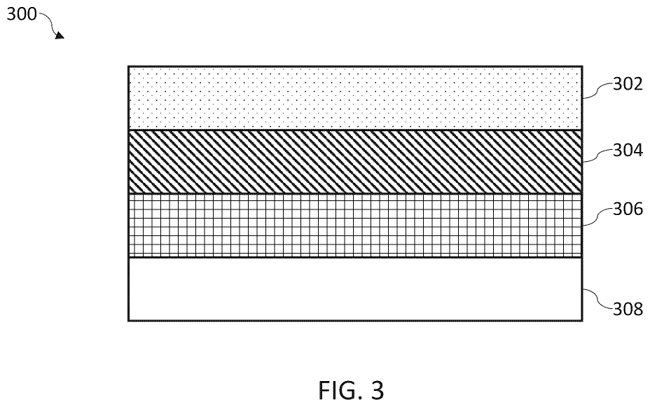

FIG. 2 is a process flow diagram depicting a method 200 for depositing a resist underlayer, according to certain embodiments described herein. FIG. 3 is a schematic view of a filmstack 300 that may be formed by method 200, according to one or more embodiments.

In an embodiment, the filmstack 300 comprises a photoresist, such as an EUV photoresist 302 sensitive to EUV electromagnetic radiation and disposed on a resist underlayer 304 and a substrate 308. In other embodiments, the photoresist may be sensitive to DUV or UV electromagnetic radiation. The substrate 308 may be any type of layer (or layers) that is to be patterned with an etching process. For example, the substrate 308 may comprise a semiconductor material (e.g., silicon), an oxide, a nitride, a metal, or the like. In an embodiment, the EUV photoresist 302 may be a chemically amplified photoresist (CAR). In some embodiments, EUV electromagnetic radiation may alter a chemistry of the EUV photoresist 302. In some instances, exposure to electromagnetic radiation may also alter the chemistry of one or more underlying underlayers below the EUV photoresist 302.

In certain embodiments, the filmstack 300 may also include a hardmask 306 (e.g., carbon containing hardmask) disposed above the layer to be patterned, such as between the resist underlayer 304 and the substrate 308. In some embodiments, the resist underlayer 304 may be disposed directly on the substrate 308. In other embodiments, one or more other interlayers may be disposed between the resist underlayer 304 and the substrate 308. In some embodiments, the EUV photoresist 302 may be a EUV lithographic positive or negative photoresist. In some embodiments, the hardmask 306 comprises a silicon carbide, silicon nitride, silicon oxide nitride, aluminum nitride, amorphous silicon, silicon oxide, or other material that is etch selective to the underlying substrate 308.

The substrate 308 may be any microelectronic substrate containing silicon, silicon oxide, aluminum, aluminum oxide, tungsten, germanium, combinations therefore, and the like. In certain embodiments, the substrate 308 may be a material such as crystalline silicon (e.g., Si<100> or Si<111>), silicon oxide, strained silicon, silicon germanium, doped or undoped polysilicon, doped or undoped silicon substrates and patterned or non-patterned substrates silicon on insulator (SOI), carbon doped silicon oxides, silicon nitride, doped silicon, germanium, gallium arsenide, glass, sapphire. The substrate may have various dimensions, such as 200 mm, 300 mm, and 450 mm or other diameter substrates, as well as, rectangular or square panels. Unless otherwise noted, embodiments and examples described herein are conducted on substrates with a 200 mm diameter, a 300 mm diameter, or a 450 mm diameter substrate.

In one embodiment, the method 200 may be used to deposit the resist underlayer 304 on the hardmask 306, as depicted in FIG. 3. In some embodiments, method 200 may begin after positioning the substrate 308 and the hardmask 306 disposed thereon in a plasma-processing chamber, such as the processing region 146 of process chamber 100. In other embodiments, method 200 may begin after the hardmask 306 is formed on the substrate 308 in the process chamber 100.

In operation 210, method 200 begins by flowing a precursor gas mixture, such as a hydrocarbon-containing gas mixture into the processing region of the process chamber. In an embodiment, the precursor gas mixture may include at least one hydrocarbon source and/or carbon-containing source. The gas mixture may further include an inert gas, a dilution gas, a nitrogen-containing gas, or combinations thereof. The hydrocarbon and/or carbon-containing source can be any liquid or gas. In one example, the precursor is vapor at room temperature, which simplifies the hardware for material metering, control and delivery to the chamber.

In one embodiment, the hydrocarbon compound has a general formula CₓH_{y}, where x has a range of between 1 and 20 and y has a range of between 1 and 20. In one embodiment, the hydrocarbon compound is an alkane. In other embodiments, the precursor gas mixture flown in operation 210 comprises CₓH_{y}N_{z}, TMS, B₂H₆, SiH₄ and WF₆ or combinations thereof.

Suitable dilution, treatment, and or inert gases such as helium (He), argon (Ar), xenon, nitrogen (N₂), N₂O, oxygen (O₂), SIF₄, NF₃, B₂H₆, and SiH₄ or combinations thereof, among others, may be added to the gas mixture. Alternatively, dilution gases may not be used during the deposition.

In the embodiments described herein, during deposition of the resist underlayer 304, the chamber may be maintained at a temperature between about 10 degrees Celsius and about 600 degrees Celsius (e.g., between about 200 degrees Celsius to about 600 degrees Celsius; or between about 500 degrees Celsius to about 600 degrees Celsius). The chamber pressure may range from about 0.3 Torr to about 30 Torr (e.g., between about 1 Torr and about 20 Torr; or between about 5 Torr and about 10 Torr).

At operation 220, RF power is applied to ignite the hydrocarbon-containing gas and generate a RF plasma in the processing region. In one embodiment, the RF power may be a dual-frequency RF power that has a high frequency component and a low frequency component. In another embodiment, the RF power may be all high-frequency RF power, for example at a frequency of about 13.56 MHz, applied at a power level between about 5 W and about 10,000 W. In one embodiment, the RF plasma may be a pulsed RF plasma utilizing plasma on/off or a pulsed radio frequency (RF) plasma technique. In some embodiments, the pulsed RF plasma technique in operation 220 includes a single pulsed plasma process using at least one of a pulsed source power signal or a pulsed bias power signal. To pulse the bias power, the radio frequency power is switched on and off during the deposition process. Pulsed RF plasma can be used to obtain high-precision plasma processing to control the dynamics of radical formation and the resulting ion radical ratio in the generated plasma. For example, pulsed RF plasma can provide for increased radical concentration since when the RF power is turned off (during the “off” phase of the pulse), the ions rapidly decay due to their heavier mass and slower movement compared to electrons. Conversely, during the “off” phase, the radical concentration can actually increase during this afterglow period, as the electrons continue to react with gas molecules, creating more radicals before they eventually recombine. The bias power frequency and the pulsing frequency may be adjusted depending on the substrate material being processed. For example, when in pulse mode, the RF power source may be pulsed at a pulse frequency between about 10 Hz to about 2000 Hz, such as about 1 kHz. The RF power source may be operated at a duty cycle (e.g., the percentage of on time during the total of on time and off time in a given cycle) that is between about 1% and about 99%, such as between about 30% and about 70%, such as about 50%.

In some embodiments, depositing the resist underlayer 304 on the hardmask 306 in operation 220 includes depositing the resist underlayer 304 such that a rapid transition between the hardmask 306 and the resist underlayer 304 occurs to form distinct layers between the hardmask 306 and the resist underlayer 304. In some embodiments, the resist underlayer 304 formed comprises a thickness between about 10 Å and about 50 Å.

In operation 220, forming the resist underlayer 304 utilizing a pulsed RF plasma technique enables control over the porosity of the resist underlayer 304 such that the formation of pinholes in the resist underlayer 304 is minimized to improve the density of the resist underlayer 304. By controlling the porosity of the resist underlayer 304, the effect of the hardmask 306 disposed below the resist underlayer 304 can be minimized. As a result, the resist underlayer 304 may therefore be engineered to improve the adhesion of the resist underlayer 304 to the hardmask 306.

After the resist underlayer 304 is deposited, method 200 may continue with operation 230 in which a post treatment process may optionally be performed on the resist underlayer 304 to modify the surface energy of the resist underlayer 304. Operation 230 may be performed to improve adhesion between the resist underlayer 304 and the EUV photoresist 302 subsequently deposited. In some embodiments, the post treatment process may include forming a C-terminated surface layer, B-terminated surface layer, Si-terminated surface layer, N-terminated surface layer, W-terminated surface layer, Sn-terminated surface layer, Pb-terminated surface layer, or a Ge-terminated surface layer on a top surface of the resist underlayer 304. The post treatment performed in operation 230 and the composition of the resulting surface layer formed on the resist underlayer 304 may depend on the composition of the EUV photoresist 302 intended to be deposited on the resist underlayer 304. In some embodiments, the surface layer formed in operation 230 may be different depending on if the EUV photoresist 302 being deposited is a CAR or a metal oxide photoresist. In some embodiments, operation 230 may include performing method 400 described herein below.

In operation 240, the EUV photoresist 302 is formed on the resist underlayer 304. In some embodiment, the resist underlayer 304 may include a surface layer formed in operation 230. In other embodiments, the EUV photoresist 302 may be formed directly on the resist underlayer 304 within intervening surface layer. In one embodiment, the EUV photoresist 302 is deposited on the resist underlayer 304 using one or more of the EUV photoresist deposition techniques known to one of ordinary skill in the art of semiconductor device manufacturing. For example, the EUV photoresist 302 may be a polymer material sensitive to a certain wavelength of electromagnetic radiation, and may be deposited through a spin coating process, CVD process, PECVD process, and the like. In an embodiment, the EUV photoresist 302 is applied over the resist underlayer 304 with a typical spin coating process.

In some embodiments, the EUV photoresist 302 is a carbon-based polymer sensitive to ultraviolet light i.e. CAR. For example, the EUV photoresist 302 may comprise a phenolic resin, an epoxy resin, or an azonapthenic resin. The chemical amplification concept of a CAR uses a photochemically-generated acid as a catalyst. The catalyst induces a cascade of chemical transformations in the resist film, providing a gain mechanism to fully convert exposed regions of the photoresist. The converted regions of the CAR are then etch selective to the unexposed regions. Thereafter, a developing process can be used to remove the exposed regions leaving the unexposed regions intact, or to remove the unexposed regions leaving the exposed regions intact.

The EUV photoresist 302 may be a positive or a negative photoresist. Preferred positive photoresists may be selected from the group consisting of a 248 nm photoresist, a 193 nm photoresist, a 157 nm photoresist, and a phenolic resin matrix with a diazonapthoquinone sensitizer. Preferred negative photoresists may be selected from the group consisting of poly-cis-isoprene and poly-vinylcinnamate.

After the EUV photoresist 302 is formed on the resist underlayer 304, method 200 may continue with operation 250, which includes patterning the EUV photoresist 302 with exposure to electromagnetic radiation and a developer. In an embodiment, the electromagnetic radiation is EUV radiation and the developing process may be a liquid developing process or a dry developing process.

The EUV photoresist 302 may be patterned to from a plurality of features. In some embodiment, the plurality of features comprises line and space structures. In other embodiments, the plurality of features comprises pillar structures. Patterned EUV photoresist having pillar structures have smaller contact areas with the resist underlayer than line and space structures. It was observed the small contact areas of pillar structures caused weak adhesion between the pillar structures of the patterned EUV photoresist and the resist underlayer. In some instances, the weak adhesion led to the pillar structures collapsing before minimum critical dimension (CD) for the pillar structures was achieved.

In an embodiment, the method 200 may continue with operation 260 which includes comprises transferring the pattern of the EUV photoresist 302 into the hardmask 306 (if present), or the substrate 308. The pattern of the resist layers may be transferred using an etching process, such as a wet etching process or a dry etching process.

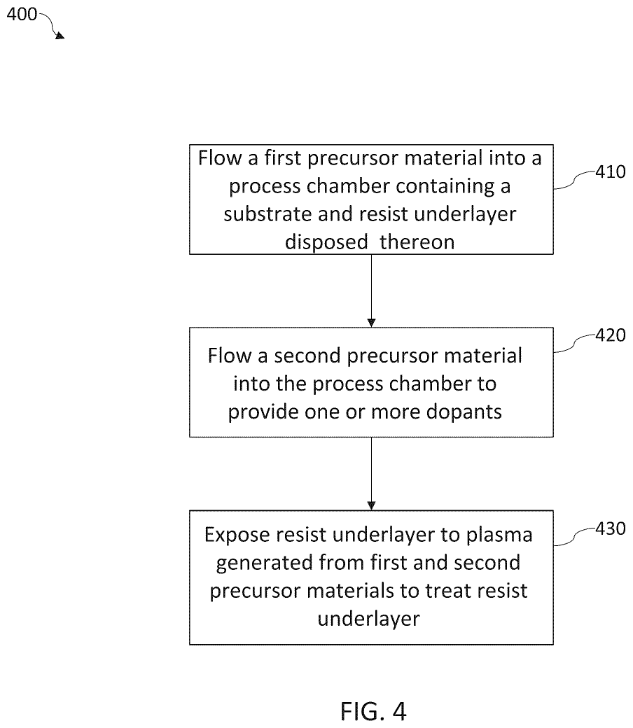

FIG. 4 is a process flow diagram depicting a method 400 which may be performed in operation 230 of method 200 for treating a top surface of the resist underlayer 304, according to certain embodiments escribed herein. In some embodiments, the method 400 may be used to form a surface layer on the resist underlayer thereby modifying the surface energy at the interface between the resist underlayer and the EUV photoresist to improve adhesion between the EUV photoresist 302 and the resist underlayer 304.

The resist underlayer 304 may be treated by exposing the resist underlayer 304 to one or more reactive dopants to change the polarity and/or dispersibility of the surface energy of the resist underlayer. The dopants may be thermally activated or reactive using a plasma.

Method 400 begins in operation 410 by flowing a first precursor material, such as a hydrocarbon-containing gas mixture into the processing region of the process chamber. The gas mixture may include at least one hydrocarbon and/or carbon-containing source. The gas mixture may further include an inert gas, a dilution gas, a nitrogen-containing gas, or combinations thereof. The hydrocarbon and/or carbon-containing source can be any liquid or gas. In one example, the precursor is vapor at room temperature, which simplifies the hardware for material metering, control and delivery to the chamber.

In one embodiment, the hydrocarbon and/or carbon-containing precursors can be either liquid or gas. In one embodiment, the hydrocarbon precursor has a general formula CₓH_{y}, where x has a range of between 1 and 20 and y has a range of between 1 and 20. In one embodiment, the hydrocarbon compound is an alkane, for example methane (CH₄). In an embodiment, which can be combined with other embodiments described herein, the flow rate of the hydrocarbon-containing gas may be from about 2 sccm to 10000 sccm.

In operation 420, method 400 continues with flowing a second precursor material into the processing region to provide one or more dopants. The resist underlayer 304 may be treated by exposing the resist underlayer 304 to a plasma formed from a suitable processing gas mixture comprising dopants to treat the resist underlayer 304. Suitable dopants for treating the resist underlayer 304 may be generated from various precursor materials, such as carbon (C), boron (B), silicon (Si), nitrogen (N), tungsten (W), lead (Pb), tin (Sn), and/or germanium (Ge) containing materials. In one embodiment, the dopant or inert species is selected from carbon, boron, nitrogen, silicon, tungsten, or a combination thereof. Examples of carbon containing precursor gases include CH₄. In one embodiment, various precursor materials can be generated from combinations of precursor materials including, for example, CH₄/N₂, CH₄/He, N₂/He, CH₄/Ne, CH₄/Ar, CH₄/Ne, CH₄/Kr, or CH₄/Xe.

Operation 420 may also include exposing the resist underlayer 304 to additional precursor gases, such as Ar, He, Xe, N₂, N₂O, NH₃, or combinations thereof. The flow rate of the additional process gases may (individually) each be from about 2 sccm to 10000 sccm.

In operation 430, RF plasma is generated in the processing region to treat the resist underlayer 304. The RF plasma may be formed by capacitive or inductive means, and may be energized by coupling RF power into the process gas mixture provided to the processing region in operations 410 and 420. The RF power may be a dual-frequency RF power that has a high frequency component and a low frequency component. The RF plasma may be formed by coupling the RF power at a suitable frequency to the aforementioned process gas within the processing region to establish and maintain the RF plasma. For example, in some embodiments, about 0 watts to about 10,000 watts of RF power at a frequency in a range from about 2 to about 162 MHz, having continuous wave or pulsing capabilities, may be provided to the process chamber to ignite and maintain the RF plasma. In an embodiment, the RF power is provided at a power between about 10 Watts and about 3000 Watt.

During the treatment of the resist underlayer 304 by the RF plasma in operation 320, the process chamber may be maintained at a temperature between about 0 degrees Celsius and about 600 degrees Celsius (e.g., between about 200 degrees Celsius to about 600 degrees Celsius; or between about 500 degrees Celsius to about 600 degrees Celsius). The chamber pressure may range from about 0.3 Torr to about 30 Torr (e.g., between about 1 Torr and about 20 Torr; or between about 5 Torr and about 10 Torr). In some embodiments, operations 420 and 430 may be performed to form a Si-terminated surface layer on the resist underlayer 304. In an embodiment, the surface layer formed on the resist underlayer 304 comprises a thickness less than about 10 Å.

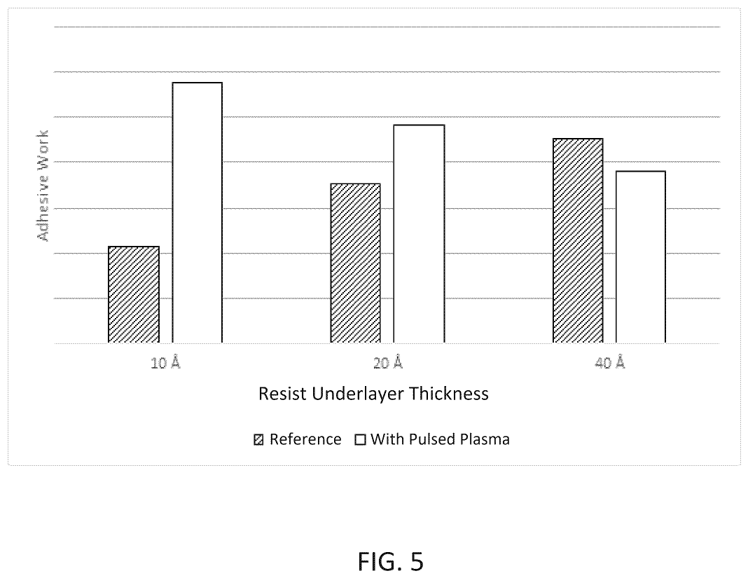

FIG. 5 illustrates a table comparing the adhesive work for removing CARs formed on resist underlayers of various thicknesses formed utilizing a pulsed RF plasma as described in method 200, and the same CARS formed on corresponding conventional resist underlayers of the same thickness. In the examples shown, adhesive work was compared for removing CARs from substrates having resist underlayers of about 10 Å, about 20 Å, and about 40 Å formed using pulsed plasma as described herein, and corresponding conventional resist underlayers formed without pulsed plasma as reference.

For context, adhesive work is an effective evaluation factor of underlayer-photoresist interaction since it takes surface energy of the photoresist (R), the liquid developer (L) and the resist underlayer on the substrate (S) into consideration. Adhesive work calculated based on surface free energy may be defined as the work needed to pull the CAR off the underlying substrate (and the resist underlayer disposed therebetween) in the developer solution. Therefore, a higher adhesive work indicates improvement in the adhesion between the CAR and the substrate due to the resist underlayer. As shown in FIG. 5, the adhesive work for removing CARs from resist underlayers having a thickness of about 10 Å, and about 20 Å increased when the resist underlayers were formed utilizing pulsed RF plasma, as compared to conventional resist underlayers. This indicates adhesive force between the CAR and substrate increased when the resist underlayer was formed utilizing pulsed plasma as compared to conventional non-pulsed plasma techniques.

While the foregoing is directed to embodiments of the present disclosure, other and further embodiments of the disclosure may be devised without departing from the basic scope thereof, and the scope thereof is determined by the claims that follow.

What is claimed is:

1. A method for processing a substrate, comprising:
disposing a substrate in a processing region of a process chamber;
flowing a precursor gas mixture into the processing region of the process chamber;
applying a pulsed RF power to the precursor gas mixture to generate a plasma in the processing region;
depositing a resist underlayer on the substrate with the plasma generated from the pulsed RF power; and
forming a patterned chemically amplified photoresist (CAR) over the resist underlayer.

2. The method of claim 1, wherein applying the pulsed RF power comprises pulsing the pulsed RF power at a pulse frequency between about 10 Hz to about 2000 Hz and at a duty cycle between about 10% and about 90%.

3. The method of claim 1, wherein the precursor gas mixture comprises a hydrocarbon compound having a general formula CₓH_{y}, wherein x has a range of between 1 and 20 and y has a range of between 1 and 20.

4. The method of claim 1, wherein the resist underlayer comprises a thickness less than about 50 Å.

5. The method of claim 1, wherein the process chamber is maintained at a temperature between about 10 degrees Celsius and about 600 degrees.

6. The method of claim 1, wherein the process chamber is maintained at a chamber pressure between about 0.3 Torr to about 30 Torr.

7. The method of claim 1, further comprising patterning the substrate using the patterned CAR.

8. The method of claim 1, further comprising forming a hardmask on the substrate prior to flowing the precursor gas mixture into the processing region.

9. The method of claim 1, wherein forming the patterned CAR comprises depositing a CAR material on the substrate and patterning the CAR material by exposing the CAR material to EUV electromagnetic radiation and a developer.

10. A method for processing a substrate, comprising:
disposing a substrate in a processing region of a process chamber;
depositing a hardmask layer over the substrate;
flowing a precursor gas mixture into the processing region of the process chamber;
applying a RF power to the precursor gas mixture to generate a plasma in the processing region;
pulsing the RF power at a pulse frequency between about 10 Hz to about 2000 Hz, and at a duty cycle between about 10% and about 90%;
depositing a resist underlayer on the hardmask layer with the plasma; and
forming a patterned chemically amplified photoresist (CAR) over the resist underlayer.

11. The method of claim 10, wherein the precursor gas mixture comprises a hydrocarbon compound having a general formula CₓH_{y}, wherein x has a range of between 1 and 20 and y has a range of between 1 and 20.

12. The method of claim 10, further comprising patterning the hardmask and the substrate using the patterned CAR.

13. The method of claim 10, wherein the resist underlayer comprises a thickness less than about 50 Å.

14. The method of claim 10, wherein forming the patterned CAR comprises depositing a CAR material on the substrate and patterning the CAR material by exposing the CAR material to EUV electromagnetic radiation and a developer.

15. A method for processing a substrate, comprising:
flowing a precursor gas mixture into a processing region of a process chamber having a substrate disposed therein;
applying a pulsed RF power to the precursor gas mixture to generate a plasma in the processing region;
depositing a resist underlayer on the substrate with the plasma generated from the pulsed RF power;
performing a surface treatment process to form a surface layer on the resist underlayer to modify a surface energy of the resist underlayer;
forming a chemically amplified photoresist (CAR) over the resist underlayer; and
patterning the CAR with a wet chemical process to form a patterned CAR over the substrate.

16. The method of claim 15, wherein applying the pulsed RF power comprises pulsing the pulsed RF power at a pulse frequency between about 10 Hz to about 2000 Hz and at a duty cycle between about 10% and about 90%.

17. The method of claim 15, wherein performing the surface treatment process comprises exposing the resist underlayer to a plasma formed from a processing gas comprising dopants having carbon (C), boron (B), silicon (Si), nitrogen (N), tungsten (W), lead (Pb), tin (Sn), and/or germanium (Ge) containing materials.

18. The method of claim 17, wherein performing the surface treatment process comprises applying RF power to the processing gas at a RF power between about 10 Watts and about 3000 Watt.

19. The method of claim 15, wherein the surface layer comprises a thickness less than about 10 Å.

20. The method of claim 15, wherein patterning the CAR comprises exposing the CAR to EUV electromagnetic radiation and a liquid developer.
